(19) United States
(12) Patent Application Publication
(10) Pub. No.: US 2019/0305213 A1
(43) Pub. Date: Oct. 3, 2019

(54) MAGNETORESISTIVE STACKS AND METHODS THEREFOR

(71) Applicant: Everspin Technologies, Inc., Chandler, AZ (US)

(72) Inventor: Jijun Sun, Chandler, AZ (US)

(73) Assignee: Everspin Technologies, Inc., Chandler, AZ (US)

(21) Appl. No.: 15/941,025

(22) Filed: Mar. 30, 2018

(51) Int. Cl. H01L 43/08; H01L 43/12; H01L 43/02; H01L 43/10; G11C 11/16

(52) U.S. Cl. CPC H01L 43/08; H01L 43/12; G11C 11/161; H01L 43/10; H01L 43/02

(57) ABSTRACT

A magnetoresistive device may include a tunnel barrier region, a magnetically fixed region positioned on one side of the tunnel barrier region, and a magnetically free region positioned on an opposite side of the tunnel barrier region. The magnetically free region may include a plurality of ferromagnetic regions and at least one nonmagnetic insertion region. At least one ferromagnetic region of the plurality of ferromagnetic regions may include a multi-layer structure comprising a first layer of cobalt, and a second layer including at least one of platinum or palladium

### TECHNICAL FIELD

The present disclosure relates to, among other things, magnetoresistive stacks and methods for fabricating and using the disclosed magnetoresistive stacks.

### INTRODUCTION

There are many inventions described and illustrated herein, as well as many aspects and embodiments of those inventions. In one aspect, the present disclosure relates to a magnetoresistive stack or structure (for example, part of a magnetoresistive memory device, magnetoresistive sensor/transducer device, etc.), and methods of manufacturing and/or using the described magnetoresistive stacks. In one embodiment, an exemplary magnetoresistive stack (for example, used in a magnetic tunnel junction (MTJ) magnetoresistive device) of the present disclosure includes one or more layers of magnetic or ferromagnetic material configured to improve the reliability, thermal stability, and/or thermal endurance of the magnetoresistive device.

Briefly, a magnetoresistive stack used in a memory device (e.g., a magnetoresistive random access memory (MRAM)) includes at least one non-magnetic layer (for example, at least one dielectric layer or a non-magnetic yet electrically conductive layer) disposed between a “fixed” magnetic region and a “free” magnetic region, each including one or more layers of ferromagnetic materials. Information is stored in the magnetoresistive memory stack by switching, programming, and/or controlling the direction of magnetization vectors in the magnetic layer(s) of the “free” magnetic region. The direction of the magnetization vectors of the “free” magnetic region may be switched and/or programmed (for example, through spin transfer torque (STT) or spin orbital torque (SOT)) by application of a write signal (e.g., one or more current pulses) through or adjacent to the magnetoresistive memory stack. In contrast, the magnetization vectors in the magnetic layers of a “fixed” magnetic region are magnetically fixed in a predetermined direction. When the magnetization vectors of the “free” magnetic region adjacent to the non-magnetic layer are in the same direction as the magnetization vectors of the “fixed” magnetic region adjacent to the non-magnetic layer, the magnetoresistive memory stack has a first magnetic state. Conversely, when the magnetization vectors of the “free” magnetic region adjacent to the non-magnetic layer are opposite the direction of the magnetization vectors of the “fixed” magnetic region adjacent to the non-magnetic layer, the magnetoresistive memory stack has a second magnetic state with a relatively higher resistance when compared to the first magnetic state. The magnetic state of the magnetoresistive memory stack is determined or read based on the resistance of the stack in response to a read current.

In some applications, a device incorporating a magnetoresistive stack (such as, for example, an MTJ device such as an MRAM) may be subject to high temperatures (during, e.g., fabrication, testing, operation, etc.). It is known that a strong perpendicular magnetic anisotropy (PMA) of the magnetoresistive stack is desirable for high temperature data retention capabilities of the device. For improved high temperature performance of the device, it is desirable to have a “free” magnetic region with high enough PMA and magnetic moment to enable the device to have a high energy barrier to thermal reversal at elevated temperatures (for example, at 260° C., the typical temperature for soldering of packaged devices onto printed circuit boards (PCBs)), and also have a reasonable switching voltage or current in the operating temperature range so that the device will have useful cycling endurance characteristics (for example, at least 10,000 cycles, or preferably more than 1 million, and more preferably over 10⁸ cycles). The disclosed magnetoresistive stacks may have some or all of these desired characteristics. The scope of the current disclosure, however, is defined by the attached claims, and not by any characteristics of the resulting device or method.

### BRIEF DESCRIPTION OF THE DRAWINGS

Embodiments of the present disclosure may be implemented in connection with aspects illustrated in the attached drawings. These drawings show different aspects of the present inventions and, where appropriate, reference numerals illustrating like structures, components, materials, and/or elements in different figures are labeled similarly. It is understood that various combinations of the structures, components, and/or elements, other than those specifically shown, are contemplated and are within the scope of the present disclosure.

For simplicity and clarity of illustration, the figures depict the general structure and/or manner of construction of the various embodiments described herein. For ease of illustration, the figures depict the different layers/regions of the illustrated magnetoresistive stacks as having a uniform thickness and well-defined boundaries with straight edges. However, a person skilled in the art would recognize that, in reality, the different layers typically have a non-uniform thickness. And, at the interface between adjacent layers, the materials of these layers alloy together, or migrate into one or the other material, making their boundaries ill-defined. Descriptions and details of well-known features (e.g., interconnects, etc.) and techniques may be omitted to avoid obscuring other features. Elements in the figures are not necessarily drawn to scale. The dimensions of some features may be exaggerated relative to other features to improve understanding of the exemplary embodiments. Cross-sectional views are simplifications provided to help illustrate the relative positioning of various regions/layers and describe various processing steps. One skilled in the art would appreciate that the cross-sectional views are not drawn to scale and should not be viewed as representing proportional relationships between different regions/layers. Moreover, while certain regions/layers and features are illustrated with straight 90-degree edges, in actuality or practice such regions/layers may be more “rounded” and gradually sloping.

Further, one skilled in the art would understand that, although multiple layers with distinct interfaces are illustrated in the figures, in some cases, over time and/or exposure to high temperatures, materials of some of the layers may migrate into or interact with materials of other layers to present a more diffuse interface between these layers. It should be noted that, even if it is not specifically mentioned, aspects described with reference to one embodiment may also be applicable to, and may be used with, other embodiments.

Moreover, there are many embodiments described and illustrated herein. The present disclosure is neither limited to any single aspect nor embodiment thereof, nor to any combinations and/or permutations of such aspects and/or embodiments. Moreover, each aspect of the present disclosure, and/or embodiments thereof, may be employed alone or in combination with one or more of the other aspects of the present disclosure and/or embodiments thereof. For the sake of brevity, certain permutations and combinations are not discussed and/or illustrated separately herein. Notably, an embodiment or implementation described herein as “exemplary” is not to be construed as preferred or advantageous, for example, over other embodiments or implementations; rather, it is intended to reflect or indicate that the embodiment(s) is/are “example” embodiment(s). Further, even though the figures and this written disclosure appear to describe the disclosed magnetoresistive stacks in a particular order of construction (e.g., from bottom to top), it is understood that the depicted magnetoresistive stacks may have a different order (e.g., the opposite order (i.e., from top to bottom)). For example, a “fixed” magnetic region may be formed on or above a “free” magnetic region or layer, which in turn may be formed on or above an insertion layer of the present disclosure.

FIG. 1 illustrates a cross-sectional view depicting various regions of an exemplary magnetoresistive stack;

FIGS. 2A-2D illustrate cross-sectional views of exemplary “free” magnetic regions of the exemplary magnetoresistive stack of FIG. 1;

FIG. 3 is an schematic diagram of an exemplary magnetoresistive memory stack/structure electrically connected to an access transistor in a magnetoresistive memory cell configuration;

FIGS. 4A-4B are schematic block diagrams of integrated circuits including a discrete memory device and an embedded memory device, each including an MRAM (which, in one embodiment is representative of one or more arrays of MRAM having a plurality of magnetoresistive memory stacks according to aspects of certain embodiments of the present disclosure);

FIG. 5 is a simplified exemplary manufacturing flow for the fabrication of the exemplary magnetoresistive stack of FIG. 1; and

FIGS. 6-7 are graphs showing experimental results obtained using magnetoresistive devices of the current disclosure in exemplary embodiments.

Again, there are many embodiments described and illustrated herein. The present disclosure is neither limited to any single aspect nor embodiment thereof, nor to any combinations and/or permutations of such aspects and/or embodiments. Each of the aspects of the present disclosure, and/or embodiments thereof, may be employed alone or in combination with one or more of the other aspects of the present disclosure and/or embodiments thereof. For the sake of brevity, many of those combinations and permutations are not discussed separately herein.

### DETAILED DESCRIPTION

It should be noted that all numeric values disclosed herein (including all disclosed thickness values, limits, and ranges) may have a variation of ±10% (unless a different variation is specified) from the disclosed numeric value. For example, a layer disclosed as being “t” units thick can vary in thickness from (t−0.1t) to (t+0.1t) units. Further, all relative terms such as “about,” “substantially,” “approximately,” etc. are used to indicate a possible variation of ±10% (unless noted otherwise or another variation is specified). Moreover, in the claims, values, limits, and/or ranges of the thickness and atomic composition of, for example, the described layers/regions, mean the value, limit, and/or range±10%.

It should be noted that the description set forth herein is merely illustrative in nature and is not intended to limit the embodiments of the subject matter, or the application and uses of such embodiments. Any implementation described herein as exemplary is not to be construed as preferred or advantageous over other implementations. Rather, the term “exemplary” is used in the sense of example or “illustrative,” rather than “ideal.” The terms “comprise,” “include,” “have,” “with,” and any variations thereof are used synonymously to denote or describe a non-exclusive inclusion. As such, a device or a method that uses such terms does not include only those elements or steps, but may include other elements and steps not expressly listed or inherent to such device and method. Further, the terms “first,” “second,” and the like, herein do not denote any order, quantity, or importance, but rather are used to distinguish one element from another. Similarly, terms of relative orientation, such as “top,” “bottom,” etc. are used with reference to the orientation of the structure illustrated in the figures being described. Moreover, the terms “a” and “an” herein do not denote a limitation of quantity, but rather denote the presence of at least one of the referenced item.

In this disclosure, the term “region” is used generally to refer to one or more layers. That is, a region (as used herein) may include a single layer (deposit, film, coating, etc.) of material or multiple layers of materials stacked one on top of another (i.e., a multi-layer structure). Further, although in the description below, the different regions and/or layers in the disclosed magnetoresistive stacks are referred to by specific names (capping region, reference region, transition region, etc.), this is only for ease of description and not intended as a functional description of the layer. Moreover, although the description below and the figures appear to depict a certain orientation of the layers relative to each other, those of ordinary skill in the art will understand that such descriptions and depictions are only exemplary. For example, though the “free” region is depicted as being “above” an intermediate region, in some aspects the entire magnetoresistive stack may be flipped such that the intermediate region is “above” the “free” region.

In one exemplary aspect, the magnetoresistive stack of the present disclosure may be implemented as a spin-torque magnetoresistive random access memory (“MRAM”) element (“memory element”). In such aspects, the magnetoresistive stack may include an intermediate region positioned (or sandwiched) between two ferromagnetic regions to form a magnetic tunnel junction (MTJ) device or an MTJ-type device. The intermediate region may be a tunnel barrier and include an insulating material, such as, e.g., a dielectric material. In other embodiments, the intermediate region may be a non-magnetic yet electrically conductive material, e.g., copper, gold, or alloys thereof. In these other embodiments, where the magnetoresistive stack includes a conductive material in between two ferromagnetic regions, the magnetoresistive stack may form a giant magnetoresistance (GMR) or GMR-type device.

Of the two ferromagnetic regions disposed on either side of the intermediate region, one ferromagnetic region may be a magnetically “fixed” (or pinned) region, and the other ferromagnetic region may be a magnetically “free” region. The term “free” is intended to refer to ferromagnetic regions having a magnetic moment that may shift or move significantly in response to applied magnetic fields or spin-polarized currents used to switch the magnetic moment vector of the “free” region. On the other hand, the words “fixed” and “pinned” are used to refer to ferromagnetic regions having a magnetic moment vector that does not move substantially in response to such applied magnetic fields or spin-polarized currents. As is known in the art, an electrical resistance of the described magnetoresistive stack may change based on whether the magnetization direction (e.g., the direction of the magnetic moment) of the “free” region adjacent to the non-magnetic layer is in a parallel alignment or in an antiparallel alignment with the magnetization direction (e.g., the direction of the magnetic moment) of the “fixed” region adjacent to the non-magnetic layer. Typically, if the two regions have the same magnetization alignment, the resulting relatively low resistance is considered as a digital “0,” while if the alignment is antiparallel the resulting relatively higher resistance is considered to be a digital “1.” A memory device (such as an MRAM) may include multiple such magnetoresistive stacks, which may be referred to as memory cells or elements, arranged in an array of columns and rows. By measuring the current through each cell, the resistance of each cell, and thus the data stored in the memory array can be read.

Switching the magnetization direction of the “free” region of a magnetoresistive stack may be accomplished by driving a tunneling current pulse through the magnetoresistive stack. The polarity of the current pulse determines the final magnetization state (i.e., parallel or antiparallel) of the “free” region. The mean current required to switch the magnetic state of the “free” region may be referred to as the critical current. The critical current is indicative of the current required to “write” data in (or the write current of) a magnetoresistive memory cell. Reducing the required write current(s) is desirable so that, among other things, a smaller access transistor can be used for each memory cell and a higher density, lower cost memory can be produced. Reduced write current requirements may also lead to greater tunnel barrier endurance and/or longevity of a magnetoresistive memory cell.

For the sake of brevity, conventional techniques related to semiconductor processing may not be described in detail herein. The exemplary embodiments may be fabricated using known lithographic processes. The fabrication of integrated circuits, microelectronic devices, micro electro mechanical devices, microfluidic devices, and photonic devices involves the creation of several layers or regions (i.e., comprising one or more layers) of materials that interact in some fashion. One or more of these regions may be patterned so various regions of the layer have different electrical or other characteristics, which may be interconnected within the region or to other regions to create electrical components and circuits. These regions may be created by selectively introducing or removing various materials. The patterns that define such regions are often created by lithographic processes. For example, a layer of photoresist is applied onto a layer overlying a wafer substrate. A photo mask (containing clear and opaque areas) is used to selectively expose the photoresist by a form of radiation, such as ultraviolet light, electrons, or x-rays. Either the photoresist exposed to the radiation, or not exposed to the radiation, is removed by the application of a developer. An etch may then be employed/applied whereby the layer (or material) not protected by the remaining resist is patterned. Alternatively, an additive process can be used in which a structure is built up using the photoresist as a template.

As noted above, in one aspect, the described embodiments relate to, among other things, methods of manufacturing a magnetoresistive stack having one or more electrically conductive electrodes, vias, or conductors on either side of a magnetic material stack. As described in further detail below, the magnetic material stack may include many different regions of material, where some of these regions include magnetic materials, whereas others do not. In one embodiment, the methods of manufacturing include sequentially depositing, growing, sputtering, evaporating, and/or providing (as noted above, herein collectively “depositing” or other verb tense (e.g., “deposit” or “deposited”)) regions which, after further processing (for example, etching) form a magnetoresistive stack.

The disclosed magnetoresistive stacks may be formed between a top electrode/via/line and a bottom electrode/via/line and, which permit access to the stack by allowing for connectivity (for example, electrical) to circuitry and other elements of the magnetoresistive device. Between the electrodes/vias/lines are multiple regions, including at least one “fixed” magnetic region (referred to hereinafter as a “fixed” region) and at least one “free” magnetic region (referred to hereinafter as a “free” region) with one or more intermediate region(s), such as, e.g., a dielectric layer (that form(s) a tunnel barrier) between the “fixed” and “free” magnetic regions. Each of the “fixed” and “free” magnetic regions may include, among other things, a plurality of ferromagnetic layers. In some embodiments, the top electrode (and/or the bottom electrode) may be eliminated, and the bit line may be formed on top of the stack.

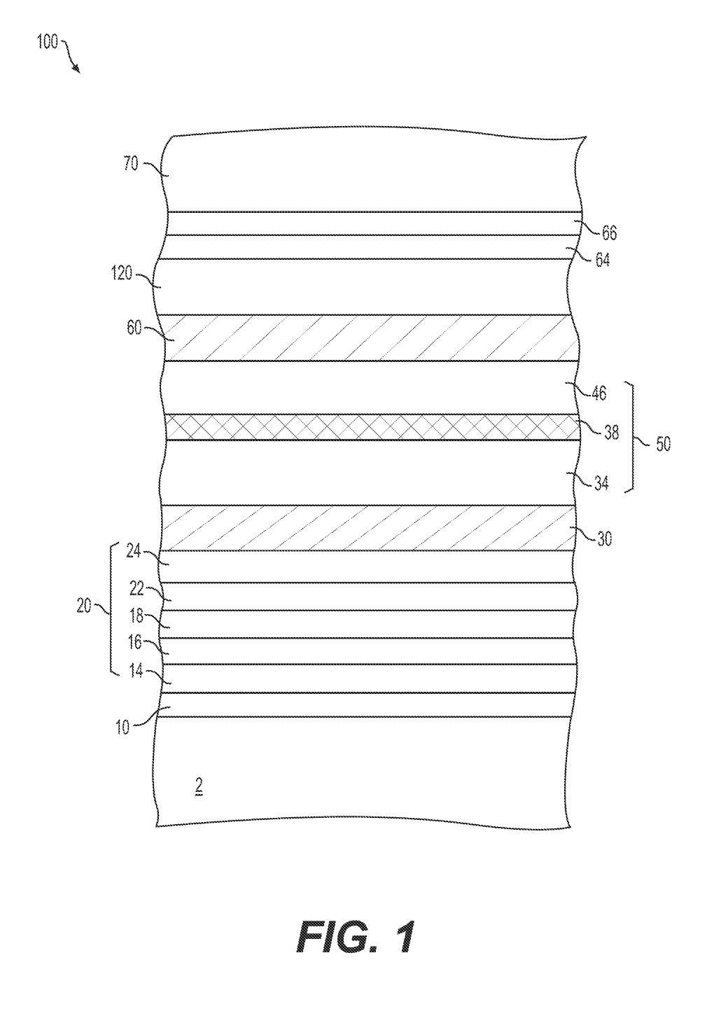

FIG. 1 is a cross-sectional view of the regions of an exemplary magnetoresistive stack 100 of the current disclosure. Magnetoresistive stack 100 may include, for example, an in-plane or out-of-plane magnetic anisotropy magnetoresistive stack (e.g., a perpendicular magnetic anisotropy magnetoresistive stack). As illustrated in FIG. 1, magnetoresistive stack 100 includes multiple regions (or layers) arranged one over the other to form a stack of regions between a first electrode 10 (e.g., a bottom electrode) and a second electrode 70 (e.g., a top electrode). When implemented as an MTJ or MTJ-like memory device, the magnetoresistive stack 100 of FIG. 1 may represent a dual spin filter structure (or a double MTJ structure) where a “free” region 50 is formed between two “fixed” regions 20 and 120. It should be noted that depiction of the magnetoresistive stack 100 as having a dual spin filter structure (in FIG. 1) is merely exemplary and not a requirement of the current disclosure. That is, the current disclosure also is applicable to magnetoresistive stacks having a different structure (e.g., a single MTJ structure where a “free” region 50 is formed over a single “fixed” region 20). It will be recognized that several other commonly-used regions or layers of stack 100 (e.g., various protective cap layers, seed layers, underlying substrate, etc.) have not been illustrated in FIG. 1 (and in subsequent figures) for clarity. The different regions of the multi-layer magnetoresistive stack 100 of FIG. 1 will be described below.

As shown in FIG. 1, the first electrode 10 may be a “bottom” electrode, and the second electrode 70 may be a “top” electrode. However, those of ordinary skill in the art will recognize that the relative order of the various regions (or layers) of magnetoresistive stack 100 may be reversed. Further, in some embodiments, the top electrode (and/or the bottom electrode) may be eliminated, and the bit line may be formed on top of the stack. The bottom and top electrodes 10, 70 may comprise an electrically conductive material, and may be part of (or be in physical contact with) electrically conductive interconnects (e.g., vias, traces, lines, etc.) of a device (e.g., MRAM) formed using the magnetoresistive stack 100. Although any electrically conductive material may be used for bottom and top electrodes 10, 70, in some embodiments, a metal such as tantalum (Ta), titanium (Ti), tungsten (W), or a composite or alloy of these elements (e.g., tantalum-nitride alloy) may be used.

Bottom electrode 10 may be formed on a planar surface of a semiconductor substrate 2 (e.g., surface of a semiconductor substrate having electrical circuits (e.g., CMOS circuits) formed thereon or therein, etc.). Although not illustrated in FIG. 1, in some embodiments, electrode 10 may include a seed layer at its interface with the overlying region (e.g., region 20). During fabrication, the seed layer may assist in the formation of the overlying region on electrode 10. The seed layer may include one or more of nickel (Ni), chromium (Cr), cobalt (Co), iron (Fe), ruthenium (Ru), Platinum (Pt), tantalum (Ta), and alloys thereof (for example, an alloy including nickel and/or chromium) or multilayers thereof. In some embodiments, the seed layer may be eliminated, and the top surface of electrode 10 itself may act as the seed layer.

With continuing reference to FIG. 1, a “fixed” region 20 may be formed on (or above) the bottom electrode 10. As explained previously, “fixed” region 20 may serve as a “fixed” magnetic region of magnetoresistive stack 100. That is, a magnetic moment vector in the “fixed” region 20 does not move significantly in response to applied magnetic fields (e.g., an external field) or applied currents used to switch the magnetic moment vector of a “free” region 50 of the magnetoresistive stack 100. It should be noted that the structure of the “fixed” region 20 illustrated in FIG. 1 is only exemplary. As known to those of ordinary skill in the art, many other configurations of the “fixed” region 20 also are possible. In general, the “fixed” region 20 may include a single layer or multiple layers stacked one on top of another. The layers of “fixed” region 20 may include alloys that include cobalt and iron and other materials (preferably cobalt, iron, and boron). Typically, the composition of materials (e.g., cobalt, iron, and boron) in the “fixed” region 20 may be selected to achieve good temperature compensation. For the sake of clarity, only certain layers of “fixed” region 20 (and regions on either side of “fixed” region 20) are illustrated in FIG. 1. Those of ordinary skill in the art will readily recognize that the “fixed” region 20 may include one or more additional layers.

In one embodiment, “fixed” region 20 may be a fixed, unpinned synthetic antiferromagnetic (SAF) region disposed on or above electrode 10. The fixed, unpinned synthetic antiferromagnetic (SAF) region may include at least two magnetic regions (i.e., made of one or more layers) 14, 18 separated by a coupling region 16. The one or more magnetic regions 14, 18 may include one or more of the ferromagnetic elements nickel, iron, and cobalt, including alloys or engineered materials with one or more of the elements palladium (Pd), platinum (Pt), chromium (Cr), and alloys thereof. The coupling region 16 may be an antiferromagnetic (AF) coupling region that includes non-ferromagnetic materials such as, for example, iridium (Ir), ruthenium (Ru), rhenium (Re), or rhodium (Rh). In some embodiments, one or both regions 14, 18 may comprise a magnetic multi-layer structure that includes a plurality of layers of (i) a first ferromagnetic material (e.g., cobalt) and (ii) a second ferromagnetic material (e.g., nickel) or a paramagnetic material (e.g., platinum). In some embodiments, regions 14, 18 may also include, for example, alloys or engineered materials with one or more of palladium (Pd), platinum (Pt), magnesium (Mg), manganese (Mn), and chromium (Cr). Additionally, or alternatively, in some embodiments, the “fixed” region 20 may include one or more synthetic ferromagnetic structures (SyF). Since SyFs are known to those skilled in the art, they are not described in greater detail herein. In some embodiments, the “fixed” region 20 may have a thickness in the range of between approximately 8 Å and approximately 300 Å, between approximately 15 Å and approximately 110 Å, greater than or equal to 8 Å, greater than or equal to 15 Å, less than or equal to 300 Å, or less than or equal to 110 Å.

In some embodiments, the “fixed” region 20 may also include one or more additional layers, such as, for example, a transition region 22 and a reference region 24, disposed at the interface between the magnetic region 18 and an overlying region (e.g., region 30, which as will be explained later may include a dielectric material in an MTJ structure). The reference and/or transition regions may include one or more layers of material that, among other things, facilitate/improve growth of the overlying intermediate region 30 during fabrication of stack 100. In one embodiment, the reference region 24 may comprise one or more (e.g., all) of cobalt, iron, and boron (for example, in an alloy—such as an amorphous alloy (e.g., CoFeB or CoFeBTa or CoFeTa)), and the transition region 22 may include a non-ferromagnetic transition metal such as tantalum (Ta), titanium (Ti), tungsten (W), ruthenium (Ru), niobium (Nb), zirconium (Zr), and/or molybdenum (Mo).

In general, the transition region 22 and the reference region 24 may have any thickness. In some embodiments, a thickness (t) of the reference region 24 may be between approximately 6-13 Å, preferably approximately 8-12 Å, and more preferably approximately 9-9.5 Å, and the thickness of the transition region 22 may be between approximately 1-8 Å, preferably approximately 1.5-5 Å, and more preferably approximately 2.5-3.5 Å. It should be noted that, in some embodiments of magnetoresistive stacks 100, both transition region 22 and reference region 24 may be provided in the “fixed” region 20. In some embodiments, the transition region 22 or both of the transition region 22 and the reference region 24 may be eliminated altogether from magnetoresistive stack 100. And, in some embodiments, only the reference region 24 may be provided in the “fixed” region 20.

“Fixed” region 20 may be deposited or formed using any technique now known or later developed, all of which are intended to fall within the scope of the present disclosure. In some embodiments, one or more of the magnetic regions of the “fixed” region 20 (e.g., regions 14, 18) may be deposited using a “heavy” inert gas (for example, xenon (Xe)), for example, at room temperature (for example, 15-40° C., and more preferably 20-30° C., and most preferably 25° C. (+/−10%)) or a conventional/typical elevated temperature. In some embodiments, the AF coupling region 16 may also be deposited using a “heavy” inert gas (for example, xenon (Xe), argon (Ar), and/or krypton (Kr)) at such temperatures. In embodiments where the transition region 22 and/or the reference region 24 are provided, they may also be deposited using a “heavy” inert gas (for example, xenon (Xe), argon (Ar), and/or krypton (Kr)) at about room temperature (for example, 15-40° C., and more preferably 20-30° C., and most preferably 25° C. (+/−10%)) or an elevated temperature (e.g., 40-60° C.).

The various regions or layers of “fixed” region 20 depicted in FIG. 1 may be deposited individually during a fabrication process. However, as would be recognized by those of ordinary skill in the art, in some embodiments, the materials that make up the various depicted regions may alloy with (intermix with, diffuse into, etc.) the materials of adjacent regions during a subsequent processing (e.g., high temperature processing operations, such as, annealing, etc.). Therefore, a person skilled in the art would recognize that, although the different regions (of “fixed” region 20 of FIG. 1) may appear as separate regions with distinct interfaces immediately after formation of these regions, after subsequent processing operations, the materials of the different regions may alloy together to form a single alloyed “fixed” region 20 having a higher concentration of different materials at interfaces between different regions. Thus, in some cases, it may be difficult to distinguish the different regions of the “fixed” region 20 (and other regions) in a finished magnetoresistive stack 100.

With continuing reference to FIG. 1, a “free” region 50, or storage region, may be provided “above” the “fixed” region 20 with an intermediate region 30 formed between the “fixed” region 20 and the “free” region 50. The relative orientation depicted in FIG. 1 is only exemplary. Those of ordinary skill will readily recognize that “free” region 50 may be provided “below” the “fixed” region 20 in the illustration of FIG. 1. As explained previously, the type of intermediate region 30 formed depends upon the type of magnetoresistive stack 100 being fabricated. For a magnetoresistive stack 100 having an MTJ structure, the intermediate region 30 may include a dielectric material and may function as a tunnel barrier. In a spin valve structure, the intermediate region 30 may include a conductive material (e.g., copper) to form a GMR-type magnetoresistive stack 100. Intermediate region 30 may be formed on (or above) a surface of the “fixed” region 20, and the “free” region 50 may be formed on (or above) a surface of the intermediate region 30. In general, intermediate region 30 may be formed on or above the “fixed” region 20 using any technique now known (e.g., deposition, sputtering, evaporation, etc.) or later developed. In some embodiments, intermediate region 30 may include an oxide material, such as, for example, magnesium oxide (MgO)ₓ or aluminum oxide (AlOₓ (e.g., Al₂O₃)), and may be formed by multiple steps of material deposition and oxidation. For example, a layer of an oxidizable material (e.g., Mg, Al, etc.) may first be deposited and the deposited layer of oxidizable material may be oxidized (using, for example, natural oxidation at temperatures less than or equal to about 35° C., plasma oxidation, etc.) to convert the oxidizable material to an oxide. In some embodiments, multiple such deposition and oxidation steps may be carried out to produce an intermediate region 30 of a desired thickness. For example, the intermediate region 30 may be formed with approximately three layers of oxidized material. In general, intermediate region 30 may have any thickness. In some embodiments, the intermediate region 30 may have a thickness between approximately 8.5-14.1 Å, preferably between approximately 9.0-13.0 Å, and more preferably between approximately 9.8-12.5 Å.

It should be noted that the construction of the “free” region 50 illustrated in FIG. 1 and described below is only exemplary, and many other constructions are possible. Notwithstanding the specific construction of the “free” region 50, as explained previously, a magnetic vector (or moment) in “free” region 50 may be moved or switched by applied magnetic fields or spin torque currents. As illustrated in FIG. 1, in some embodiments, the “free” region 50 may include one or more regions 34, 46 formed of a magnetic or ferromagnetic material separated by one or more insertion region(s) 38. The insertion region 38 may provide either ferromagnetic coupling or antiferromagnetic coupling between the ferromagnetic regions 34 and 46 of the “free” region 50. In some embodiments, the materials of ferromagnetic regions 34, 46 may include alloys of one or more of ferromagnetic elements, such as, nickel (Ni), iron (Fe), and/or cobalt (Co), and in some embodiments, boron. In some embodiments, the ferromagnetic regions 34, 46 comprise cobalt (Co), iron (Fe), and boron (B) (referred to as CoFeB). For ease of description, in the description below, ferromagnetic region 34 may be referred to as the first ferromagnetic region and ferromagnetic region 46 may be referred to as the second ferromagnetic region.

In some embodiments, one or both of the ferromagnetic regions 34, 46 may be formed by directly depositing a boron-containing ferromagnetic alloy (such as, for example, CoFeB). The exact composition of the CoFeB alloy may depend upon the application. In some embodiments, the CoFeB alloy may have a composition between approximately 10-50 atomic percent (at. %) of cobalt (Co), approximately 10-35 at. % of boron (B), and the remainder being iron (Fe), or preferably between approximately 20-40 at. % cobalt (Co), approximately 15-30 at. % boron (B), and the remainder being iron (Fe), or more preferably approximately 55% at. % iron (Fe), approximately 25 at. % boron (B), and the remaining cobalt (Co). In some embodiments, additional elements may be added to the CoFeB alloys of ferromagnetic regions 34, 46 to provide improved magnetic, electrical, or microstructural properties. In some embodiments, a thin layer of iron (Fe) (e.g., approximately 1-3 Å thick) may also be provided at one or both the interfaces of the ferromagnetic regions 34, 46 with intermediate regions 30 and 60. Moreover, in some embodiments, an iron (Fe) rich layer or region may be provided adjacent to ferromagnetic regions 34, 46. For example, an iron (Fe) rich region (e.g., a layer of iron (Fe)) may be deposited between ferromagnetic region 34 and intermediate region 30. In addition, or alternatively, an iron (Fe) rich region (e.g., a layer of iron (Fe)) may be deposited between ferromagnetic region 46 and intermediate region 60.

Insertion region 38 may include any nonmagnetic material (now known or developed in the future) that can provide coupling (e.g., ferromagnetic or antiferromagnetic) between the ferromagnetic regions on either side of the intermediate region 38. That is, insertion region 38 may provide coupling between the ferromagnetic region 34 on the one side and the ferromagnetic region 46 on the other side. In some embodiments, the insertion region 38 may include materials such as tantalum (Ta), tungsten (W), molybdenum (Mo), ruthenium (Ru), rhodium (Rh), rhenium (Re), iridium (Ir), chromium (Cr), osmium (Os), and their combinations. Although “free” region 50 of FIG. 1 is illustrated as including two ferromagnetic regions 34, 46 separated by a single insertion region 38, this is only exemplary. In general, “free” region 50 may have any number of ferromagnetic regions with insertion regions 38 provided between the adjacent ferromagnetic regions.

In general, the ferromagnetic regions 34, 46 may have any thickness. In some embodiments, the thickness of the ferromagnetic regions 34, 46 may each be between approximately 3-30 Å (preferably approximately 6-17 Å, or more preferably between approximately 8-15 Å). The thickness of insertion region 38 is typically chosen to provide strong ferromagnetic or antiferromagnetic coupling between the ferromagnetic regions on either side of the insertion region 38. In general, the thickness of insertion region 38 may be chosen such that it does not form a continuous layer, which would break or otherwise inhibit the exchange coupling between adjacent ferromagnetic regions 34, 46. Instead, the material of insertion region 38 may mix with the materials of the adjacent ferromagnetic regions 34, 46 to form a uniform layer, or may form a layer that is not continuous, so that the adjacent ferromagnetic regions 34, 46 are directly exchange coupled to each other and the entire structure acts as a single ferromagnetic “free” region 50 of stack 100. In general, the thickness of the insertion region 38 may be between approximately 1-12 Å (preferably approximately 2-6 Å, or more preferably between approximately 2.5-4 Å). In some embodiments, the as-deposited thickness of the insertion region 38 may be less than approximately 5 Å, or between approximately 2 Å and 4.5 Å, or approximately 3 Å.

With continuing reference to FIG. 1, after forming “free” region 50 as described above, a second intermediate region 60 may be formed on or above the “free” region 50. In embodiments of magnetoresistive stack 100 used in an MTJ device, both regions 30 and 60 may include a dielectric material and may function as a tunnel barrier. In some embodiments, intermediate region 60 may include the same material, and may be formed in a similar manner, as intermediate region 30. However, this is not a limitation, and in some embodiments, regions 30 and 60 may include different dielectric materials. For example, region 30 may include MgO and region 60 may include AlOₓ (e.g., Al₂O₃). In some embodiments, region 60 also may be similar in thickness to region 30. In other embodiments, region 60 may have a thickness that is larger or smaller than the thickness of region 30. In some embodiments, region 60 may have a thickness between approximately 3-14 Å, preferably between approximately 5-12 Å, and more preferably between approximately 6-10 Å. Although not illustrated in FIG. 1, in some embodiments, a dusting of an interfacial material (e.g., iridium (Ir), chromium (Cr), etc.) may also be provided at the interface between the “free” region 50 and the second intermediate region 60. This interfacial material, deposited as, e.g., a discontinuous patchwork of material (as opposed to a continuous layer that would break exchange coupling between the mating layers), may result in a high perpendicular magnetic anisotropy (PMA) of the resulting magnetoresistive stack 100. Moreover, those of ordinary skill in the art also will recognize that region 60 also may include a non-magnetic conductive material, such as, e.g., copper.

A second “fixed” region 120 may be formed on or above intermediate region 60. Although “fixed” region 120 is illustrated as a single layer in FIG. 1, “fixed” region 120 may also include a multi-layered structure similar to that described with reference to “fixed” region 20. In some embodiments, a spacer region 64 and/or a capping region 66 may be formed above the second “fixed” region 120, and electrode 70 may be formed above the capping region 66. The capping region 66 may be formed from any suitable conductive material (for example, a suitable metallic material, including, but not limited to, tantalum (Ta), titanium (Ti), tungsten (W), etc.) and may have any suitable thickness between approximately 50-150 Å. In some embodiments, the thickness of the spacer region 64 may be between approximately 10-50 Å, or preferably between approximately 15-40 Å, or more preferably between approximately 20-30 Å. The spacer region 64 may be formed of a non-ferromagnetic material, such as, e.g., ruthenium (Ru) or an alloy of ruthenium (Ru). In some embodiments, spacer region 64 may include cobalt (Co), iron (Fe), boron (B), or an alloy thereof (e.g., CoFeB). In some embodiments, the spacer region 64 may be formed of a bilayer structure comprising ruthenium (Ru) and/or a CoFeB layer. In some embodiments, the thickness of the spacer region 64 may be approximately 5-50 Å, or preferably approximately 10-35 Å, or more preferably approximately 22-28 Å.

As explained previously, the magnetoresistive stack 100 of FIG. 1 represents a dual spin filter structure where a “free” region 50 is formed between a first “fixed” region 20 and a second “fixed” region 120. However, this structure is only exemplary. In some embodiments, the second “fixed” region 120 may be eliminated to form a magnetoresistive stack having a single MTJ (magnetic tunnel junction) structure. Further, the structures of “free” region 50 and the “fixed” regions 20 and 120 described with reference to FIG. 1 are only exemplary. For example, U.S. Pat. Nos. 8,686,484; 9,136,464; and 9,419,208, each assigned to the Assignee of the current application and incorporated by reference in its entirety herein, disclose several exemplary magnetoresistive stacks, and methods of making such stacks. Specifically, “fixed” regions 20, 120 and “free” region 50 may have any of the structures and configurations disclosed in these references. Additionally, a few exemplary alternate configurations of the “free” region 50 of FIG. 1 are described below.

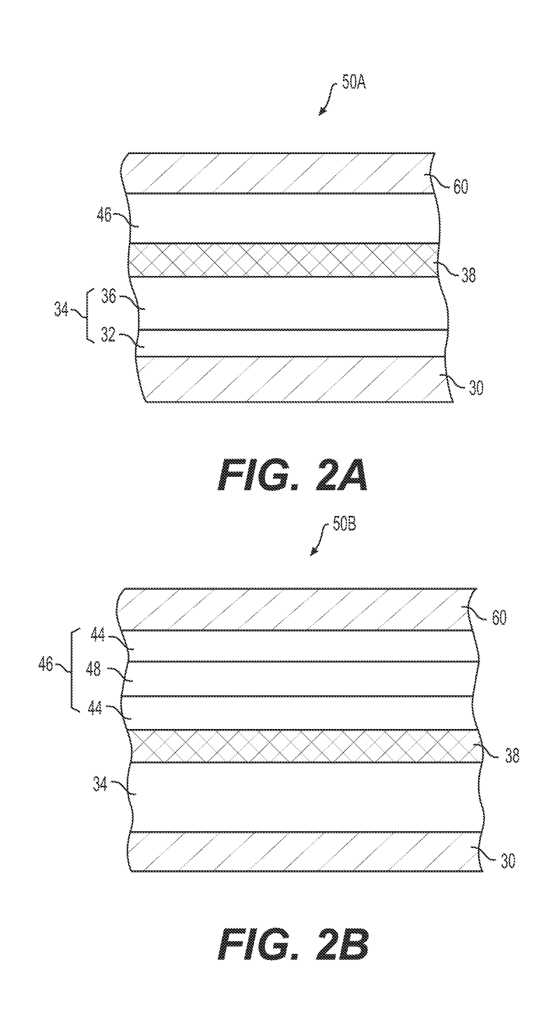

The exemplary “free” region 50 of FIG. 1 includes a first ferromagnetic region 34 and a second ferromagnetic region 46, both including CoFeB, separated from each other by an insertion region 38. However, as explained above, this is only exemplary and many other configurations of “free” region 50 are possible. FIG. 2A illustrates another exemplary configuration of a “free” region 50A that may be used in stack 100. In “free” region 50A, the first ferromagnetic region 34 of FIG. 1 is replaced with a boron-free ferromagnetic region 36 deposited adjacent a boron-rich ferromagnetic region 32. U.S. Provisional Patent Application No. 62/591,945 (filed on Nov. 29, 2017), incorporated by reference in its entirety herein, describes other similar configurations. Experiments have shown that, in some embodiments, such a configuration of “free” region 50A improves the high temperature performance of the resulting magnetoresistive stack 100.

The exact composition of the materials in regions 32 and 36 of “free” region 50A may depend upon the application. In some embodiments, the boron-rich region 32 may be a 2-9 Å thick region that includes between about 30 at. % or greater and less than about 100 at. % of boron (B), and preferably between approximately 40 to 60 at. % of boron (B), and more preferably between approximately 45 to 55 at. % of boron (B). And, the boron-free region 36 may include a CoFe alloy having between approximately 4 to 96 at. % cobalt (Co) and the remainder being iron (Fe), or preferably between approximately 20 to 80 at. % cobalt (Co) and the remainder being iron (Fe), or more preferably approximately 25-75 at. % cobalt (Co) and the remainder being iron (Fe). In some embodiments, boron-free region 36 may include an alloy of cobalt (Co) and iron (Fe) with cobalt (Co) in the range of approximately 4 to 96 at. % (in some embodiments, about 50%). It is also contemplated that substantially pure cobalt (Co) may be used as the boron-free material.

The thickness and composition of insertion region 38 and second ferromagnetic region 46 of “free” region 50A may be similar to those in “free” region 50 of FIG. 1. In some embodiments, an approximately 3 Å thick insertion region 38 including one or more of molybdenum (Mo), tantalum (Ta), tungsten (W), chromium (Cr), hafnium (Hf), or zirconium (Zr), and a second ferromagnetic region 46 comprising a boron-containing ferromagnetic alloy such as, for example, CoFe55B25 may be used. Although not illustrated in FIG. 2A, in some embodiments, an approximately 1-3 Å thick ferromagnetic region comprising essentially of iron may also be positioned between ferromagnetic region 46 and intermediate region 60. It should be noted that although FIG. 2A illustrates only the first ferromagnetic region 34 (of FIG. 1) as being replaced with a boron-free ferromagnetic region 36 and a boron-rich ferromagnetic region 32, this is only exemplary. In some embodiments, the second ferromagnetic region 46 of “free” region 50A may also include a similar structure. In some embodiments, the first ferromagnetic region 34 may have a structure similar to that of FIG. 1 (e.g., comprising a single region of a CoFeB alloy) and the second ferromagnetic region 46 may have a structure similar to that of FIG. 2A.

FIG. 2B illustrates another exemplary configuration of a “free” region 50B that may be used in stack 100. In “free” region 50B of FIG. 2B, the first ferromagnetic region 34 may include a CoFeB alloy as described with reference to “free” region 50 (of FIG. 1), and the second ferromagnetic region 46 may include a multi-layer structure comprising alternating layers of material—first layers 44 and second layer 48. Although only two first layers 44 are shown, those of ordinarily skill in the art will understand that a greater or lesser number of first layers 44 may be provided. That is, one of the first layers 44 may be eliminated, thereby leaving a bi-layer structure of first layer 44 and a second layer 48. Moreover, although only a single second layer 48 is shown, those of ordinary skill will understand that a greater number of second layers 48 may be provided. Still further, any suitable number of alternating bi-layer structure (including a first layer 44 and second layer 48) may be provided. In some embodiments, the first layer 44 may include cobalt (Co) and the second layer 48 may include platinum (Pt) or palladium (Pd). It is also contemplated, that in some embodiments, materials such as palladium (Pd), a terbium-cobalt alloy (TbCo), an iron-platinum alloy (FePt), etc. may also be used as the second layer 48. The insertion region 38 and the first ferromagnetic region 34 of “free” region 50B may be similar (e.g., in thickness, composition, etc.) to those in “free” regions 50 and 50A described previously. In some embodiments, the insertion region 38 may include molybdenum (Mo) and the first ferromagnetic region 34 may include a boron-containing ferromagnetic alloy such as, for example, CoFe55B25. In some embodiments, the insertion region 38 may be optimized to better suit the properties of the multi-layer structure (e.g., alternating layers of Co and Pt described) used in the second ferromagnetic region 46. For example, in some embodiments, an insertion region 38 of a different thickness and/or of a different material (e.g., tantalum (Ta), tungsten (W), chromium (Cr), hafnium (Hf), or zirconium (Zr)) may be used. Further, in some embodiments, the insertion region 38 may include materials, which can maintain perpendicular magnetic anisotropy of the first ferromagnetic region 34 and also promote the growth of layers 44 and 48 in the second ferromagnetic region 46 for improving PMA, and keep ferromagnetic regions 34 and 46 coupled through the insertion region 38

Although not a requirement, in some embodiments, both the first layer 44 and the second layer 48 may have a thickness between about 1-6 Å. In some embodiments, the thickness of the first layer 44 and the second layer 48 may be substantially similar, while in other embodiments, one of the layers may be thicker than the other. In some embodiments, the thickness of one or both of the first and second layers 44, 48 may be in the order of their lattice constants. For example, the lattice constants of Cobalt (Co) have values between about 2.5 and 4.1 Å, and platinum (Pt) has a lattice constant of about 3.9 Å. Therefore, in some embodiments, second ferromagnetic region 46 may have a superlattice structure comprising multiple alternating layers of cobalt (Co) having a thickness less than or equal to about 6 Å and platinum (Pt) having a thickness less than or equal to about 6 Å. As will be explained later, experimental results of a stack 100 having a “free” region 50B that included a ferromagnetic region with a multi-layer structure according to the present disclosure showed improvements in the high temperature properties of the stack 100.

As alluded to above, although the second ferromagnetic region 46 of “free” region 50B is shown as having a tri-layer structure, this is only exemplary. In general, any number of alternating layers (e.g., of cobalt (Co) and platinum (Pt)) may be used to form the ferromagnetic region 46. Typically, for a dual spin filter (DSF) stack structure, it may be desirable to have cobalt (Co) as the material that interfaces with the dielectric material of the second intermediate region 60. Therefore, in some embodiments where “free” region 50B is used as a ferromagnetic region of a DSF stack, first layer 44 may form the outermost layer of ferromagnetic region 46. However, this is not a requirement. In some embodiments (for example, when the second ferromagnetic region 46 is used in a single MTJ structure), as illustrated in FIG. 2C, the second ferromagnetic region 46 of a “free” region 50C may have a bi-layer structure with the second layer 48 forming the outermost layer or region 46.

In general, the second ferromagnetic region 46 may include any number of stacked first layers 44 (e.g., 1-5 or greater than 5) and second layers 48. FIG. 2D illustrates an exemplary “free” region 50D with a second ferromagnetic region 46 having three first layers 44 alternating with three second layers 48, two form three bilayer structures formed sequentially. In embodiments where “free” region 50D of FIG. 2D is used with a DSF stack, an additional first layer 44 may be provided as the outermost layer that interfaces with the intermediate region above. In “free” region 50D, the first layers 44 may include cobalt (Co) having a thickness between about 1-6 Å and the second layers 48 may include platinum (Pt) having a thickness between about 1-6 Å.

It should be noted that although FIGS. 2B-2D illustrate only the ferromagnetic region on one side of the interface region 38 (i.e., second ferromagnetic region 46) as having a multi-layer structure, this is only exemplary. In some embodiments, both the first and second ferromagnetic regions 34, 46 may have a multi-layer structure described in conjunction with any of FIGS. 2B-2D. In some embodiments, one or both the first and second ferromagnetic regions 34, 46 may have a portion or region including a multi-layer structure described in conjunction with any of FIGS. 2B-2D (e.g., to satisfy the other requirements of the device with this free region stack). In some embodiments, the first ferromagnetic region 34 may have a multi-layer structure (similar to the configuration of the second ferromagnetic region 46 of FIGS. 2B-2D) and the second ferromagnetic region 46 may have a configuration similar to the first ferromagnetic region 34 of FIGS. 2B-2D.

It should also be noted that the above-described compositions and thicknesses of the various regions are as-deposited values, and are only exemplary. For example, although first layer 44 is described as comprising about 1-6 Å thick layer of cobalt (Co), and the second layer is described as comprising about 1-6 Å thick layer of platinum (Pt), these are estimated as-deposited values. In some embodiments, the described thicknesses and compositions of the different regions of stack 100 are the target thicknesses and composition of the sputter targets used in the deposition of the various layers and regions. As known to those of ordinary skill in the art, experimental variations in these thicknesses and compositions can be expected. Further, as known to those of ordinary skill in the art, over time and/or exposure to high temperatures (such as, for example, during annealing, BEOL processing, etc.), the materials of the various regions and layers may alloy with each other to form a more homogenous structure without distinct interfaces demarcating the different regions. In such a structure, cobalt (Co) and platinum (Pt) of adjacent first and second regions 44, 48 may alloy with (or diffuse into) each other. As a result of such alloying, over time, the second ferromagnetic region 46 of FIGS. 2C-2D may have a composition that includes the materials of both the layers. However, in some embodiments, an increased concentration of a material may still be noticeable at different regions (e.g., interfaces) of the layer upon analysis.

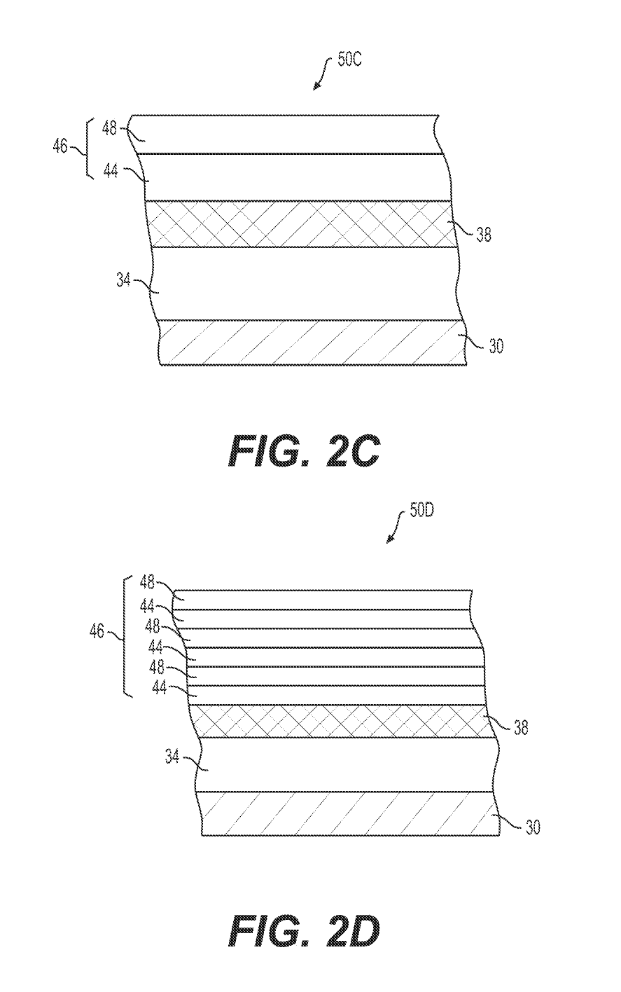

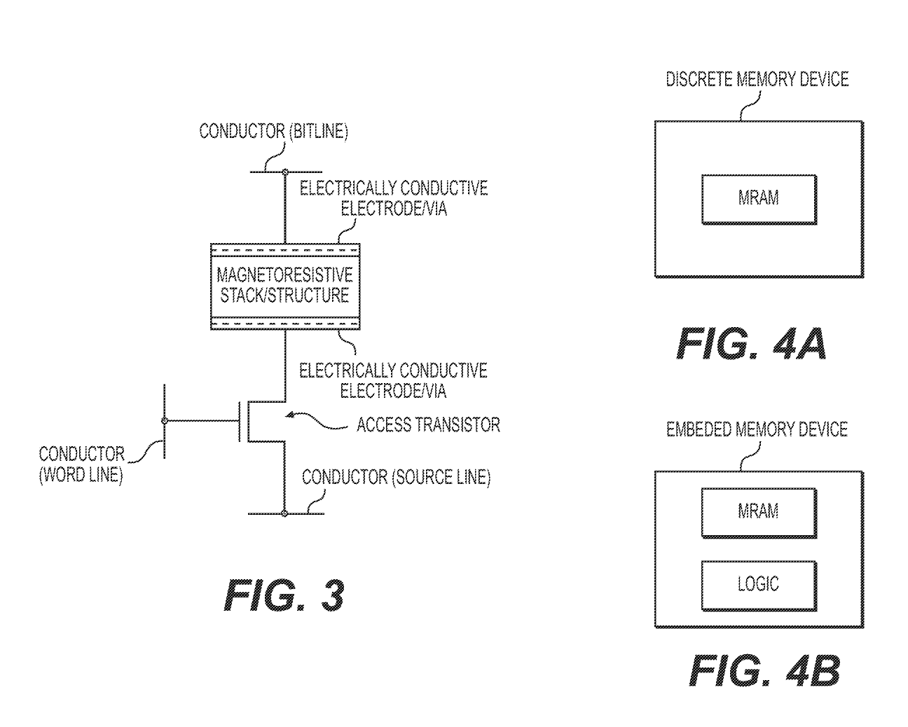

As alluded to above, magnetoresistive stack 100 may be implemented in a sensor architecture or a memory architecture (among other architectures). For example, in a memory configuration, the magnetoresistive stack 100 may be electrically connected to an access transistor and configured to couple or connect to various conductors, which may carry one or more control signals, as shown in FIG. 3. The magnetoresistive stack 100 of the current disclosure may be used in any suitable application, including, e.g., in a memory configuration. In such instances, the magnetoresistive stack 100 may be formed as an integrated circuit comprising a discrete memory device (e.g., as shown in FIG. 4A) or an embedded memory device having a logic therein (e.g., as shown in FIG. 4B), each including MRAM, which, in one embodiment is representative of one or more arrays of MRAM having a plurality of magnetoresistive stacks, according to certain aspects of certain embodiments disclosed herein.

Exemplary methods of fabricating an exemplary magnetoresistive stack 100 (e.g., magnetoresistive stack 100 of FIG. 1 having a “free” region 50B of FIG. 2B) will now be described. It should be appreciated that the described methods are merely exemplary. In some embodiments, the methods may include a number of additional or alternative steps, and in some embodiments, one or more of the described steps may be omitted. Any described step may be omitted or modified, or other steps added, as long as the intended functionality of the fabricated magnetoresistive stack/structure remains substantially unaltered. Further, although a certain order is described or implied in the described methods, in general, the steps of the described methods need not be performed in the illustrated and described order. Further, the described methods may be incorporated into a more comprehensive procedure or process having additional functionality not described herein.

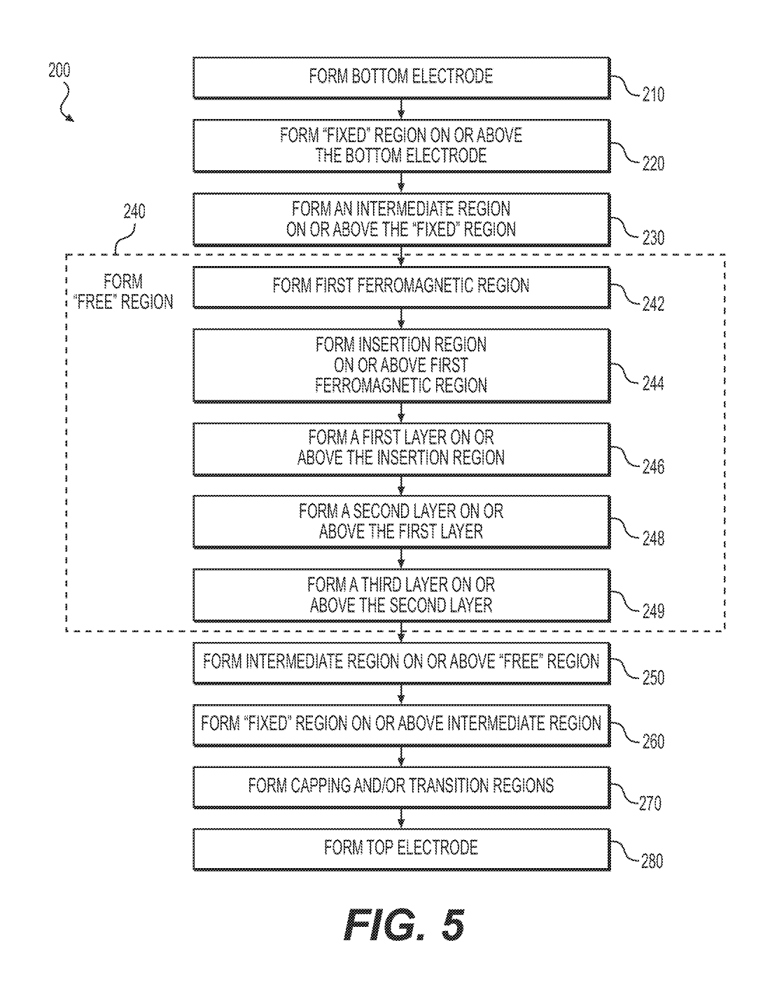

FIG. 5 depicts a flow chart of an exemplary method 200 of fabricating an exemplary magnetoresistive stack 100, according to the present disclosure. In the discussion below, reference will be made to both FIGS. 1 and 2B. A first electrode (e.g., bottom electrode 10) may be first formed on the backend (surface with circuitry) of a semiconductor substrate 2 by any suitable process (step 210). A “fixed” region 20 then may be formed on or above an exposed surface of electrode 10 (step 220). In some embodiments, “fixed” region 20 may be formed by providing (e.g., sequentially) the different regions (e.g., regions 14, 16, 18, 22, and 24) that comprise the “fixed” region 20 on the surface of electrode 10. An intermediate region 30 then may be formed on or above an exposed surface of the “fixed” region 20 (step 230). A “free” region 50 may then be formed on or above the exposed surface of the intermediate region 30 (step 240).

In some embodiments, the “free” region 50 may be formed by first providing a ferromagnetic alloy (such as, for example, CoFeB) to form a first ferromagnetic region 34 on the exposed surface of the intermediate region 30 (step 242). As explained above, the first ferromagnetic region 34 may have an iron-rich layer disposed at the interface with intermediate region 30. Next, an insertion region 38 may be formed by providing a layer of molybdenum (Mo) (or tantalum (Ta), tungsten (W), chromium (Cr), hafnium (Hf), nickel-chromium alloy (NiCr), platinum (Pt), ruthenium (Ru), or zirconium (Zr)) on or above the exposed surface of the first ferromagnetic region 34 (step 244). A layer of, for example, cobalt (Co) may then be provided on or above the exposed surface of insertion region 38 to form the first layer 44 (step 246). A layer of, for example, platinum (Pt) may then be provided on or above the exposed surface of the first layer 44 to form the second layer 48 (step 248). A third layer, e.g., a layer of cobalt (Co) (for example) may further be provided on or above the second layer to form another layer 44 (similar to the first layer 44) and complete the “free” region 50 (step 249). Instead of forming the third, however, the first layer 44 and second layer 48 may complete “free” region 50, or the first layer 44 and second layer 48 bi-layer structure may be repeated one or more times. A dielectric material may then be provided on the exposed surface of the “free” region 50 to form second intermediate region 60 (step 250), and a second “fixed” region 120 may be formed on the exposed surface of region 60 (step 260). Similar to step 220 above, the “fixed” region 120 may be formed by sequentially providing the different regions that comprise the “fixed” region 120 on the surface of intermediate region 60. A spacer region 64 and a capping region 66 may be formed on or above (i.e., on an exposed surface of) the “fixed” region 120 (step 270), and the second electrode 70 may be formed on the exposed surface of region 66 (step 280). It should be noted that, in some embodiments, some of the above-described steps (or regions) may be eliminated to form other embodiments of magnetoresistive stacks. For example, to form an exemplary magnetoresistive stack having a single MTJ structure, step 260 (i.e., form “fixed” region) may be eliminated.

Any suitable method may be used to form the different regions of the magnetoresistive stack 100. Since suitable integrated circuit fabrication techniques (e.g., deposition, sputtering, evaporation, plating, etc.) that may be used to form the different regions are known to those of ordinary skill in the art, they are not described here in greater detail. In some embodiments, forming some of the regions may involve thin-film deposition processes, including, but not limited to, physical vapor deposition techniques such as ion beam sputtering and magnetron sputtering. And, forming thin insulating layers (e.g., intermediate regions 30 and 60, which form tunnel barrier layers) may involve physical vapor deposition from an oxide target, such as by radio-frequency (RF) sputtering, or by deposition of a thin metallic film followed by an oxidation step, such as oxygen plasma oxidation, oxygen radical oxidation, or natural oxidation by exposure to a low-pressure oxygen environment.

In some embodiments, formation of some or all of the regions of magnetoresistive stack 100 may also involve known processing steps such as, for example, selective deposition, photolithography processing, etching, etc., in accordance with any of the various conventional techniques known in the semiconductor industry. In some embodiments, during deposition of the disclosed “fixed” and “free” regions, a magnetic field may be provided to set a preferred easy magnetic axis of the region (e.g., via induced anisotropy). Similarly, a strong magnetic field applied during the post-deposition high-temperature anneal step may be used to induce a preferred easy axis and a preferred pinning direction for any antiferromagnetically pinned materials.

As known to those of ordinary skill in the art, a reduction in the temperature dependence of magnetic moment and an increase in the perpendicular magnetic anisotropy (PMA) of a magnetoresistive stack improves the high temperature (for example, at approximately 260° C. for embedded MRAM applications) data retention capabilities of magnetoresistive devices using such stacks. To evaluate the temperature dependence on exemplary characteristics of a “free” region having a ferromagnetic region with a multi-layer construction, experiments were conducted using magnetoresistive stacks with two different configurations of the “free” region. In one configuration, the “free” region included two ferromagnetic regions of CoFeB separated by a molybdenum (Mo) insertion region and a thin layer of iron (Fe) on the sides of the ferromagnetic regions opposite the molybdenum (Mo) layer (e.g., having a structure Fe/CoFeB1/Mo/CoFeB2/Fe). These samples will hereinafter be referred to as the baseline stack. In another configuration, one of the ferromagnetic regions (second ferromagnetic region or CoFeB2) of the baseline stack was replaced with a layer of cobalt (Co) and a layer of platinum (Pt) (i.e., having a structure similar to that of FIG. 2C). These samples will hereinafter be referred to as the multi-layer stack. As explained in greater detail below, results from these experiments indicate that the multi-layer stacks have better high temperature characteristics.

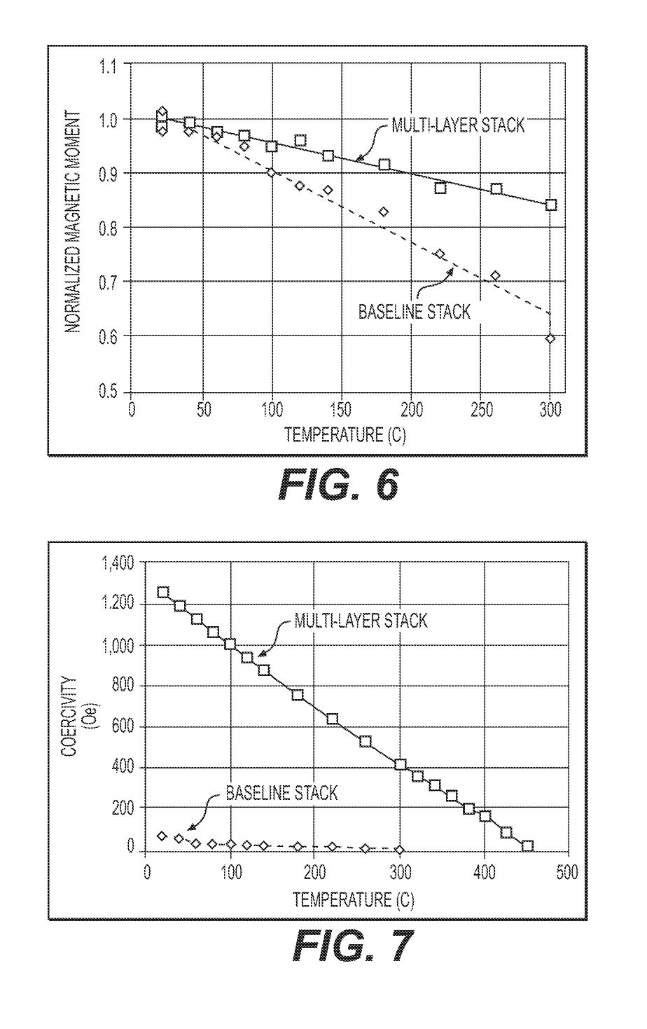

FIG. 6 is a graph that compares magnetic moment versus temperature for the multi-layer stack and the baseline stack. The y-axis of FIG. 6 is a normalized value of the observed magnetic moment (which is an indicator of the torque that will be experienced in an external magnetic field) and the x-axis is the temperature in centigrade (° C.). As can be seen in FIG. 6, for both stacks, the magnetic moment decreased with an increase in temperature. However, while the magnetic moment of the baseline stack decreased by about 29% (from the room temperature value) at 260° C., the magnetic moment of the multi-layer stack decreased only by about 13%. The observed reduction in the temperature dependence of magnetic moment in the multi-layer stack is expected to improve the high temperature properties of a magnetoresistive device using such a stack having a multi-layer structure described above in connection with FIGS. 2B-2D.

FIG. 7 is graph that shows the magnetic coercivity (Hc) of baseline and multi-layer stacks at different temperatures. In FIG. 7, the y-axis indicates the magnetic coercivity in Oersted (Oe) and the x-axis indicates the temperature in centigrade (° C.). Magnetic coercivity is an indicator of the ability of a ferromagnetic material to withstand an external magnetic field without being demagnetized. As can be seen in FIG. 7, while the coercivity at 260° C. for the baseline stack is only about 5 Oe, the coercivity for the multi-layer stack at 260° C. is about 530 Oe. As known to those of ordinary skill in the art, for magnetoresistive devices, a high coercivity is desirable for relatively high(er) energy barrier and better data retention. Thus, a magnetoresistive device using a disclosed multi-layer stack is expected to have better high temperature properties as compared to devices using baseline stacks.

In some aspects, a magnetoresistive device is disclosed. The magnetoresistive device may include a tunnel barrier region, a magnetically fixed region positioned on one side of the tunnel barrier region, and a magnetically free region positioned on an opposite side of the tunnel barrier region. The magnetically free region may include a plurality of ferromagnetic regions and at least one nonmagnetic insertion region. At least one ferromagnetic region of the plurality of ferromagnetic regions may include a multi-layer structure comprising a first layer of cobalt, and a second layer including at least one of platinum or palladium.

In various embodiments the disclosed magnetoresistive device may include one or more of the following additional or alternative aspects: the insertion region may include at least one of tantalum, tungsten, molybdenum, ruthenium, rhodium, rhenium, iridium, chromium, hafnium, zirconium, or osmium; each layer of the multi-layer structure may include a thickness between about 1-6 Å; at least one ferromagnetic region of the plurality of ferromagnetic regions may include an alloy of cobalt, iron, and boron; at least one ferromagnetic region of the plurality of ferromagnetic regions may include an alloy of cobalt, iron, and boron, wherein the at least one ferromagnetic region may include an iron rich region at an interface of the at least one ferromagnetic region and the tunnel barrier region; at least one ferromagnetic region of the plurality of ferromagnetic regions may include adjacently positioned regions of a boron-free ferromagnetic layer and a boron-containing ferromagnetic layer; the tunnel barrier region may be a first tunnel barrier region and the magnetically fixed region may be a first magnetically fixed region, and wherein the magnetoresistive device may further comprise a second tunnel barrier region positioned on a side of the magnetically free region opposite the first tunnel barrier region, and a second magnetically fixed region positioned on a side of the second tunnel barrier region opposite the magnetically free region; the multi-layer structure may include at least two layers of cobalt separated by a layer of platinum or palladium; the multi-layer structure may include at least five layers of cobalt; the tunnel barrier region may include one of magnesium oxide and aluminum oxide.

In some aspects, a method of fabricating a magnetoresistive device is disclosed. The method may include forming a magnetically fixed region, forming a tunnel barrier region on one side of the magnetically fixed region, and forming a magnetically free region on an opposite side of the tunnel barrier region, wherein forming the magnetically free region may include forming a plurality of ferromagnetic regions separated by a nonmagnetic insertion region, wherein forming at least one ferromagnetic region of the plurality of ferromagnetic regions may include forming a first layer of cobalt adjacent to a first layer of platinum or palladium.

In various embodiments the method may include one or more of the following additional aspects: the first layer of cobalt or the first layer of platinum or palladium includes a thickness between about 1-6 Å; the insertion region may include at least one of tantalum, tungsten, molybdenum, ruthenium, rhodium, rhenium, iridium, chromium, or osmium; forming the plurality of ferromagnetic regions may include forming at least one ferromagnetic region of the multiple ferromagnetic regions to include an alloy of cobalt, iron, and boron; forming the plurality of ferromagnetic regions may include forming at least one ferromagnetic region of the plurality of ferromagnetic regions to include an alloy of cobalt, iron, and boron, wherein forming the at least one ferromagnetic region may include forming an iron rich layer at an interface of the at least one ferromagnetic region and the tunnel barrier region; the tunnel barrier region may be a first tunnel barrier region and the magnetically fixed region may be a first magnetically fixed region, wherein the method may further comprise forming a second tunnel barrier region on a side of the magnetically free region opposite the first tunnel barrier region, and forming a second magnetically fixed region on a side of the second tunnel barrier region opposite the magnetically free region; forming the plurality of ferromagnetic regions may include forming at least one ferromagnetic region of the plurality of ferromagnetic regions by depositing adjacently positioned regions of a boron-free ferromagnetic layer and a boron-containing ferromagnetic layer; the method may further comprise forming a second layer of cobalt adjacent to the first layer of platinum or palladium on a side opposite to the first layer of cobalt; the method may further comprises forming a second layer of cobalt and a second layer of platinum or palladium; forming the tunnel barrier region may include depositing an oxidizable material and oxidizing the deposited oxidizable material.

Although various embodiments of the present disclosure have been illustrated and described in detail, it will be readily apparent to those skilled in the art that various modifications may be made without departing from the present disclosure or from the scope of the appended claims.

What is claimed is:

1. A magnetoresistive device, comprising:
a tunnel barrier region;
a magnetically fixed region positioned on one side of the tunnel barrier region; and
a magnetically free region positioned on an opposite side of the tunnel barrier region, wherein the magnetically free region includes a plurality of ferromagnetic regions and at least one nonmagnetic insertion region, and wherein at least one ferromagnetic region of the plurality of ferromagnetic regions includes a multi-layer structure comprising:
a first layer of cobalt; and
a second layer including at least one of platinum or palladium.

2. The magnetoresistive device of claim 1, wherein the insertion region includes at least one of tantalum, tungsten, molybdenum, ruthenium, rhodium, rhenium, iridium, chromium, hafnium, zirconium, or osmium.

3. The magnetoresistive device of claim 1, wherein each layer of the multi-layer structure includes a thickness between about 1-6 Å.

4. The magnetoresistive device of claim 1, wherein at least one ferromagnetic region of the plurality of ferromagnetic regions includes an alloy of cobalt, iron, and boron.

5. The magnetoresistive device of claim 1, wherein at least one ferromagnetic region of the plurality of ferromagnetic regions includes an alloy of cobalt, iron, and boron, and
wherein the at least one ferromagnetic region includes an iron rich region at an interface of the at least one ferromagnetic region and the tunnel barrier region.

6. The magnetoresistive device of claim 1, whereon at least one ferromagnetic region of the plurality of ferromagnetic regions includes adjacently positioned regions of a boron-free ferromagnetic layer and a boron-containing ferromagnetic layer.

7. The magnetoresistive device of claim 1, wherein the tunnel barrier region is a first tunnel barrier region and the magnetically fixed region is a first magnetically fixed region, and wherein the magnetoresistive device further comprises:
a second tunnel barrier region positioned on a side of the magnetically free region opposite the first tunnel barrier region; and
a second magnetically fixed region positioned on a side of the second tunnel barrier region opposite the magnetically free region.

8. The magnetoresistive device of claim 1, wherein the multi-layer structure includes at least two layers of cobalt separated by a layer of platinum or palladium.

9. The magnetoresistive device of claim 1, wherein the multi-layer structure includes at least five layers of cobalt.

10. The magnetoresistive device of claim 1, wherein the tunnel barrier region includes one of magnesium oxide and aluminum oxide.

11. A method of fabricating a magnetoresistive device, comprising:
forming a magnetically fixed region;
forming a tunnel barrier region on one side of the magnetically fixed region;
forming a magnetically free region on an opposite side of the tunnel barrier region, wherein forming the magnetically free region includes forming a plurality of ferromagnetic regions separated by a nonmagnetic insertion region, and wherein forming at least one ferromagnetic region of the plurality of ferromagnetic regions includes forming a first layer of cobalt adjacent to a first layer of platinum or palladium.

12. The method of claim 11, wherein the first layer of cobalt or the first layer of platinum or palladium includes a thickness between about 1-6 Å.

13. The method of claim 11, wherein the insertion region includes at least one of tantalum, tungsten, molybdenum, ruthenium, rhodium, rhenium, iridium, chromium, or osmium.

14. The method of claim 11, wherein forming the plurality of ferromagnetic regions includes forming at least one ferromagnetic region of the multiple ferromagnetic regions to include an alloy of cobalt, iron, and boron.

15. The method of claim 11, wherein forming the plurality of ferromagnetic regions includes forming at least one ferromagnetic region of the plurality of ferromagnetic regions to include an alloy of cobalt, iron, and boron, and
wherein forming the at least one ferromagnetic region includes forming an iron rich layer at an interface of the at least one ferromagnetic region and the tunnel barrier region.

16. The method of claim 11, wherein the tunnel barrier region is a first tunnel barrier region and the magnetically fixed region is a first magnetically fixed region, and wherein the method further comprises:
forming a second tunnel barrier region on a side of the magnetically free region opposite the first tunnel barrier region; and
forming a second magnetically fixed region on a side of the second tunnel barrier region opposite the magnetically free region.

17. The method of claim 11, whereon forming the plurality of ferromagnetic regions includes forming at least one ferromagnetic region of the plurality of ferromagnetic regions by depositing adjacently positioned regions of a boron-free ferromagnetic layer and a boron-containing ferromagnetic layer.

18. The method of claim 11, further comprises forming a second layer of cobalt adjacent to the first layer of platinum or palladium on a side opposite to the first layer of cobalt.

19. The method of claim 11, further comprises forming a second layer of cobalt and a second layer of platinum or palladium.

20. The method of claim 11, wherein forming the tunnel barrier region includes depositing an oxidizable material and oxidizing the deposited oxidizable material.
